(19) United States
(12) Patent Application Publication
(10) Pub. No.: US 2026/0092960 A1
(43) Pub. Date: Apr. 2, 2026

(54) RF CALIBRATION DEVICE, RF CALIBRATION METHOD AND NON-TRANSITORY COMPUTER READABLE STORAGE MEDIUM THEREOF FOR CALIBRATING RF SYSTEM

(71) Applicant: LITE-ON TECHNOLOGY CORPORATION, Taipei (TW)

(72) Inventor: Jin-Jye CHOU, Taipei (TW)

(21) Appl. No.: 19/215,394

(22) Filed: May 22, 2025

Related U.S. Application Data
(60) Provisional application No. 63/700,824, filed on Sep. 30, 2024.

(30) Foreign Application Priority Data
Mar. 5, 2025 (TW) 114108101

(51) Int. Cl. G01R 29/08

(52) U.S. Cl. CPC G01R 29/0892

(57) ABSTRACT

The invention is an RF calibration method for calibrating an RF system. The RF calibration method includes providing, by an edge computing processor of a decision computing module of an RF calibration device, multiple calibration parameter range sets, corresponding to multiple Markov states, in a calibration database of the decision computing module to a calibration control module of the RF calibration device. The RF calibration method also includes receiving, by a calibration analysis module of the RF calibration device, an output signal of the RF system. The RF calibration method also includes the calibration control module using the multiple calibration parameter range sets to calibrate the RF system through a system processor of the RF system, until a rejection of the output signal received by the calibration analysis module is greater than a threshold.

This application claims the benefit of U.S. provisional application Ser. No. 63/700,824, filed Sep. 30, 2024, and Taiwan application Serial No. 114108101, filed Mar. 5, 2025, the disclosure of which are incorporated by reference herein in its entirety.

### TECHNICAL FIELD

The disclosure relates in general to calibration techniques for radio frequency (RF) system, and more particularly, to techniques of RF calibration device, RF calibration method and non-transitory computer readable storage medium thereof for calibrating RF system.

### BACKGROUND

In conventional techniques, RF signals are separated, by orthogonal method, to two component signals, I (signal with same phase, In-phase) and Q (orthogonal signal, Quadratic-phase), for processing. Some of chips with IQ signal synthesizing function (with DAC function) have built-in register being configured to adjust RF output signals for calibrating RF system (such as DAC38J84 of TI), or Additional hardware and specified algorithm are added into RF system for calibrating RF system.

Also in conventional techniques, techniques of closed loop are used for fine-tuning signals, wherein system calibrates and compares signals by using a feedback signal, to measure status of actual DC offset and IQ imbalance after each calibrating. Additionally, the current techniques generally process DC offset and IQ imbalance separately as two separated events, wherein IQ imbalance is calibrated after the calibration of DC offset is done.

However, if some of the RF designs are unavailable to be calibrated by using closed loop techniques (such as discrete design), using open loop techniques is the only way for calibrating DC offset and IQ imbalance. For open loop techniques, there are no feedback signal for calibrating reference, and each parameter needs to be modulated in step way within the adjustable range, until the output fits requirements. For example, if 4 parameters have to be modulated and the adjustable range of each parameters is 0-63, then in the worst case, 16,777,216 (64⁴) times of modulation have to be executed for completing the calibrating process.

Also, regarding calibrating DC offset and IQ imbalance separately and considering DC offset and IQ imbalance affecting the system varying with (such frequency as frequency-dependence but flatness), the processing time of calibration for each frequency of the system may be as high as several hours.

Thus, there are needs of technique for shortening the calibrating processing time while using an open-loop method to calibrate the RF system, and while applying it to the automated production test environment.

### SUMMARY

The present disclosure describes techniques of processing calibration of QI transmitting paths in an RF system, and an edge computing can be used for establishing a Markov chain database, during the mass-production process, to use open-loop method for calibrating the RF system and to accelerate the process of RF calibration for saving costs.

The first aspect of the present disclosure features an RF calibration device for calibrating an RF system. The RF calibration device includes a calibration control module coupled to a system processor in the RF system. The RF calibration device also includes a calibration analysis module coupled to the calibration control module and the RF system and configured to receive an output signal from the RF system. The RF calibration device also includes a decision computing module coupled to the calibration control module and configured to provide multiple calibration parameter range sets in multiple of Markov chain data to the calibration control module. The calibration control module provides the multiple calibration parameter range sets to the system processor to enable the system processor using the multiple calibration parameter range sets for calibrating the RF system, until a rejection of the output signal received by the calibration analysis module is greater than a threshold.

The second aspect of the present disclosure features an RF calibration method for calibrating an RF system. The RF calibration method also includes providing, by a decision computing module of an RF calibration device, multiple calibration parameter range sets in multiple Markov chain data to a calibration control module of the RF calibration device. The RF calibration method also includes receiving, by a calibration analysis module of the RF calibration device, an output signal of the RF system. The RF calibration method also includes providing, by the calibration control module, the multiple calibration parameter range sets to a system processor of the RF system, to enable the system processor using the multiple calibration parameter range sets for calibrating the RF system, until a rejection of the output signal received by the calibration analysis module is greater than a threshold.

The third aspect of the present disclosure features a non-transitory computer readable storage medium, including multiple instructions. The multiple instructions enables a controller, a computing device or a computer performing the RF calibration method of the second aspect of the present disclosure.

The details of one or more disclosed implementations are set forth in the accompanying drawings and the description below. Other features, aspects, and advantages will become apparent from the description, the drawings and the claims.

### BRIEF DESCRIPTION OF THE DRAWINGS

FIG. 1 is a diagram illustrating an example RF system with a discrete designed structure, according to some implementations of the present disclosure.

FIG. 2 is a diagram illustrating an RF module of the RF system, according to some implementations of the present disclosure.

FIG. 3 is a function block diagram illustrating an example RF calibration device for calibrating the RF system, according to some implementations of the present disclosure.

FIG. 4 is a diagram illustrating a cloud system and multiple decision computing modules, according to some implementations of the present disclosure.

FIG. 5 is a diagram illustrating an example Markov chain, according to some implementations of the present disclosure.

FIG. 6 is a diagram illustrating another example Markov chain, according to some implementations of the present disclosure.

FIG. 7 is a diagram illustrating rejection relations between the corresponding LO signal and image signal, and the single tone signal of the RF output signal, according to some implementations of the present disclosure.

FIG. 8 is a flowchart illustrating an example RF calibration procedure for calibrating RF module, according to some implementations of the present disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The terms “comprise,” “comprising,” “include,” “including,” “has,” “having,” etc. used in this specification are open-ended and mean “comprises but not limited.” The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

These illustrative examples are given to introduce the reader to the general subject matter discussed here and are not intended to limit the scope of the disclosed concepts. The following sections describe various additional features and examples with reference to the drawings in which like numerals indicate like elements, and directional descriptions are used to describe the illustrative embodiments but, like the illustrative embodiments, should not be used to limit the present disclosure. The elements included in the illustrations herein may not be drawn to scale.

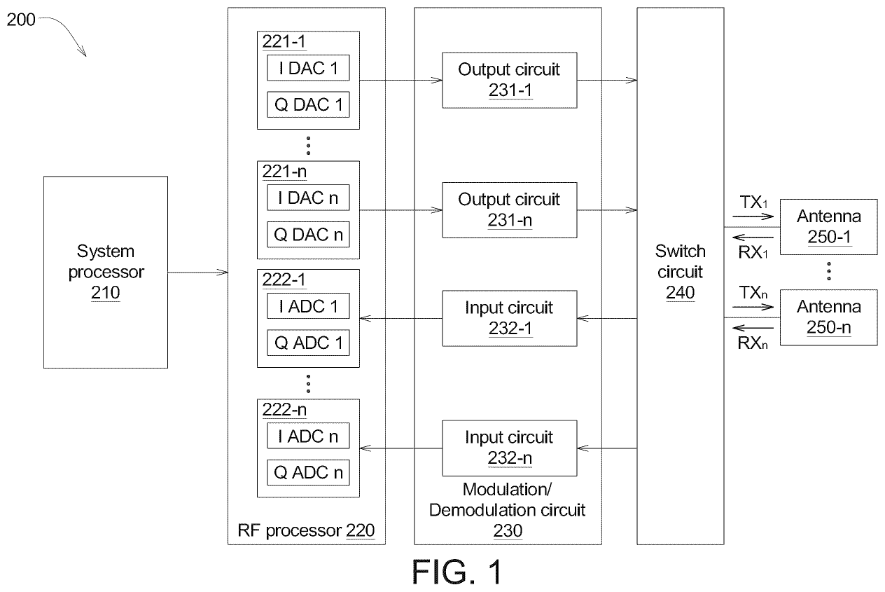

FIG. 1 is a diagram illustrating an example RF system 200 with a discrete designed structure, according to some implementations of the present disclosure. The RF system 200 includes a system processor 210, an RF processor 220, a modulation/demodulation circuit 230, a switch circuit 240 and antennas 250-1 to 250-n. The system processor 210 can be used for controlling RF output signals (TX) generated by the RF processor 220 and the modulation/demodulation circuit 230 or RF input signals (RX) received by the RF processor 220 and the modulation/demodulation circuit 230. As shown in FIG. 1, on the RF transmitting path, the RF processor 220 can include RF processing modules 221-1 to 221-n (with digital to analog converter (DAC) function), based on different frequency points (frequency points f₁-fₙ), and the RF processing modules 221-1 to 221-n can be used for processing two component signals, I (In-phase) signal and Q (Quadratic-phase) signal, and then the output signals (output signals TX₁ to TXₙ) of the single tone corresponding to different frequency points can be modulated and synthesized by the corresponding output circuits 231-1 to 231-n in the modulation/demodulation circuit 230 for outputting to corresponding antennas 250-1 to 250-n. The output circuits also can be referred as modulator circuits. On the RF receiving path, the RF processor 220 can also include the RF processing modules 221-1 to 221-n (with analog to digital converter (ADC) function), based on the different frequency points (frequency points f₁-fₙ), and the RF processing modules 221-1 to 221-n can be used for processing input signals (RX₁ to RXₙ) of the single tone received by antennas 250-1 to 250-n into two component signals, and then the input signals (RX₁ to RXₙ) can be filtered and demodulated by the corresponding input circuits 232-1 to 232-n in the modulation/demodulation circuit 230 into two component signals, I signal and Q signal. The input circuits also can be referred as demodulator circuits.

Specifically, regarding the synthesis of the two component signals, I signal and Q signal (such as through the RF processing module 221-1 and the output circuit 231-1), an asymmetry of amplitude and phase of each of I and Q signals may occur during the circuit generation process, which is also referred as IQ imbalance. IQ imbalance may cause unexpected noises, such as an image signal occurring at the position of the image frequency. This noise (image signal) may affect the data transmission quality of the RF system, such as causing lower signal-to noise ratio (SNR) and error vector magnitude (EVM), or higher bit error rate (BER), which causes that output signals cannot be demodulated.

Additionally, I signal and signal may respectively occur DC offset causing rejection between the local oscillator (LO) signal and the output single tone signal to worsen, which affects the quality of the final output signal. Thus, IQ signals at each frequency points in the RF system need to be calibrated, especially during manufacturing process, to make the RF system meet the basic functional requirements (for transmitting output signals in certain quality).

For calibrating the RF system, The single tone signal output by the RF system can be set as X(t), which can be represented as:

$$X ( t ) = {A}_{C} cos ( 2 π {f}_{c} t + ∅ ( t ) ) \qquad equation ( 1 )$$

For an ideal the RF system, two component signals, I signal and Q signal can, be respectively represented as:

$${X}_{I} ( t ) = {A}_{C} cos ( ∅ ( t ) ) \qquad equation ( 2 )$$

$${X}_{Q} ( t ) = {A}_{C} sin ( ∅ ( t ) ) \qquad equation ( 3 )$$

However, for a non-ideal RF system, amplitude A_{c} and phase Ø(t) of each I and Q signals may occur imbalance (ΔA and ΔØ), such that, based on the equation (2) above, X_{Q}(t) can be represented as following:

$${X}_{Q} ( t ) = ( {A}_{C} + Δ A ) sin ( ∅ ( t ) + Δ∅ ) \qquad equation ( 4 )$$

For simplifying, amplitude A_{c} of X_{I}(t) can be normalized, thus two component signals, I signal and Q signal can be respectively represented as:

$${X}_{I}^{′} ( t ) = cos ( ∅ ( t ) ) \qquad equation ( 5 )$$

$${X}_{Q}^{′} ( t ) = ( 1 + Δ A / {A}_{C} ) s in ( ∅ ( t ) + Δ ∅ ) \qquad equation ( 6 )$$

Herein, ΔA/A_{c} can be defined as Δg, which is variation of gain mismatch, and the equation (6) above can be represented as:

$${X}_{Q}^{′} ( t ) = ( 1 + Δ g ) sin ( ∅ ( t ) + Δ∅ ) \qquad equation ( 7 )$$

While considering DC offset of each of I and Q signals, DC offset values on I and Q signals can be respectively represented by δ_{I} and δ_{Q}, by which the equations (5) and (7) above can be respectively represented as:

$${X}_{I} ( t ) = cos ( ∅ ( t ) ) + {δ}_{I} \qquad equation ( 8 )$$

$${X}_{Q} ( t ) = ( 1 + Δ A / {A}_{C} ) sin ( ∅ ( t ) + Δ ∅ ) + {δ}_{Q} \qquad equation ( 9 )$$

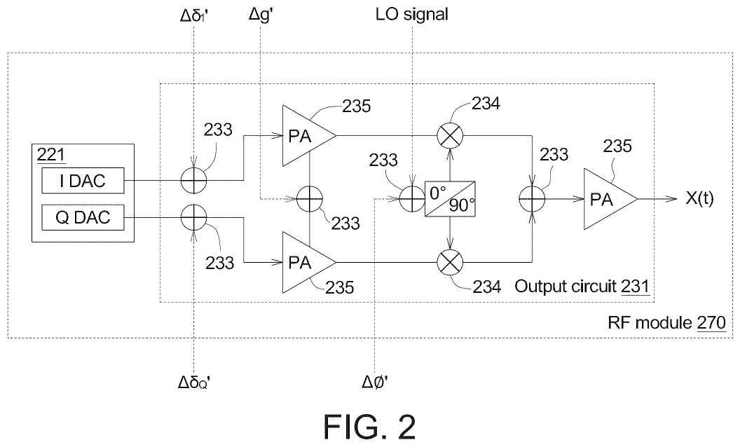

FIG. 2 is a diagram illustrating the RF module 270 of the RF system (such as the RF system 200 in FIG. 1), according to some implementations of the present disclosure. The RF module 270 corresponding to the same frequency point may include an RF processing module 221 (such as anyone of the RF processing modules 221-1 to 221-n) and an output circuit 231 (such as anyone of the output circuits 231-1 to 231-n corresponding to anyone of the RF processing modules 221-1 to 221-n). The output circuit 231 includes multiple adders 233, multiple multipliers 234 and multiple amplifiers 235. As shown in FIG. 2, for calibrating the RF module 270 of the RF system, an in-phase signal DC offset calibration parameter Δδ_{I}′, a quadrature-phase DC offset calibration parameter Δδ_{Q}′, a gain calibration parameter Δg′ and a phase calibration parameter ΔØ′ in the output circuit 231 are mainly adjusted for calibrating the single tone signal ST, on the output path, of the I and Q signals, to achieve accuracy requirements. The in-phase signal DC offset calibration parameter Δδ_{I}′, and the quadrature-phase DC offset calibration parameter Δδ_{Q}′ are respectively used for calibrating DC offset of each of I and Q signals, and the gain calibration parameter Δg′ and the phase calibration parameter ΔØ′ are respectively used for calibrating amplitude and phase of each of I and Q signals, to improve the mismatch of the gain and the phase between I signal and Q signal. The relations between single tone signal ST and I and Q signals (X_{I}(t) and X_{Q}(t)), and each of the calibration parameters above can be referred to equations (1) to 9 as described above. It can be noticed that, in ideal scenario, the LO signal provided by the RF system, any obvious signal should not occur at the frequency point of the LO signal in the output single tone signal ST. However, due to DC offsets of each of I and Q signals, the single tone signal ST may be caused to couple to the frequency point of the LO signal, such that the output end may include LO signal. Thus, during calibration, it is required to minimize the LO signal in the single tone signal ST (or to almost eliminate it) at the same time.

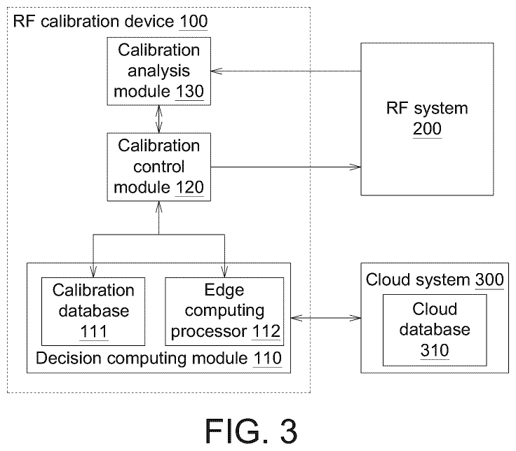

It can be understood that, during the aforementioned calibration process, the used value of each calibration parameter may be different due to RF processing modules (such as anyone of the RF processing modules 221-1 to 221-n) and output circuits (such as anyone of the output circuits 231-1 to 231-n corresponding to anyone of the RF processing modules 221-1 to 221-n) in the RF module corresponding to different frequency points. Thus, the value of the calibration parameters to be used at each frequency point needs to be determined before the calibration. Or, if only a single frequency point is considered and the same calibration parameter is applied to all frequency points, this, however, will cause differences in the quality of the output signals at different frequency points, that is, the output signal at certain frequency point may be poor. The technique of using Markov decision is further provided by the present disclosure to determine the calibration parameters required for each frequency point, which will be described in detail referring to FIGS. 3 to 6 as follows.

FIG. 3 is a function block diagram illustrating an example RF calibration device 100 for calibrating the RF system 200, according to some implementations of the present disclosure. As shown in FIG. 3, the RF calibration device 100 includes a decision computing module (such as Markov decision computing module) 110, a calibration control module 120 and a calibration analysis module 130. The calibration analysis module 130 is coupled to the calibration control module 120, and the calibration control module 120 is coupled to the decision computing module 110. The calibration control module 120 and the calibration analysis module 130 are respectively coupled to the RF system 200 to be calibrated (also can be referred as device under test (DUT)). For example, the calibration control module 120 is coupled to the system processor (such as the system processor 210 in FIG. 1) of the RF system 200, such that the system processor of the RF system 200 may use different values of calibration parameters (such as within different calibration parameter ranges) to calibrate and adjust the output signal of RF module (such as the RF module 270 in FIG. 2), corresponding to certain frequency point, in the RF system. Also, the calibration analysis module 130 is coupled to the output end of the RF system 200 (such as one of the antennas 250-1 to 250-n in FIG. 1) to receive the output signal (such as output single tone signal ST) of the output end of the RF module, corresponding to certain frequency point, in the RF system, for determining whether output signal at certain frequency meets the quality requirements.

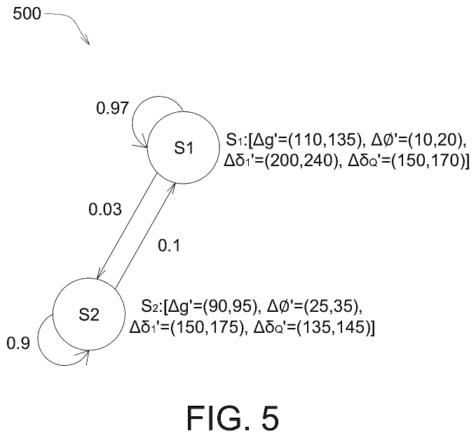

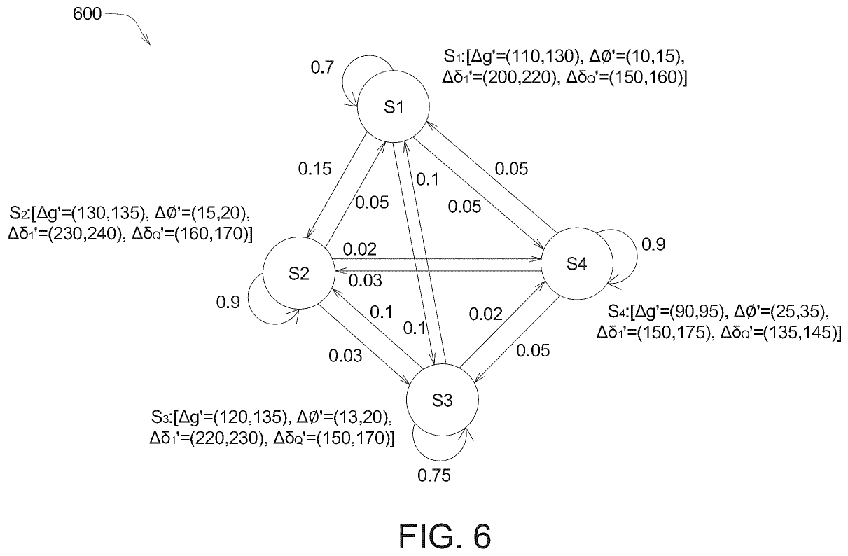

In some embodiments, the decision computing module 110 includes a calibration database 111 and an edge computing processor 112, wherein the calibration database 111 stores calibration parameters (such as the in-phase signal DC offset calibration parameter Δδ_{I}′, the quadrature-phase DC offset calibration parameter Δδ_{Q}′, the gain calibration parameter Δg′ and the phase calibration parameter ΔØ′) of multiple manufacturing machines of each production lines in a same area (such as in the same factory), and the edge computing processor 112 is communicatively coupled to the calibration database 111 for retrieving calibration parameters of the multiple manufacturing machines to form Markov chain data. Wherein, the Markov chain data include multiple Markov states (as shown in FIGS. 5 and 6), and the multiple Markov states are used as multiple calibration parameter range sets for providing to the calibration control module 120. Specifically, each calibration parameter range set includes calibration parameter ranges of each calibration parameter. Thus, the calibration control module 120 may provide the multiple calibration parameter range sets generated by the decision computing module 110 to the RF system 200, such that the system processor of the RF system 200 may calibrate the output signal of each frequency point of the RF system 200.

In some implementations, the RF calibration device 100 can be implemented by using a desktop computer, a laptop, a mobile device, a server, or other devices that can provide the same functions. In some implementations, the decision computing module 110 may be coupled to a cloud system including a cloud database 310. The cloud database 310 can store data of calibration parameter range sets that are used to complete RF calibration of corresponding RF systems, provided by decision computing modules in different regions, and provide calibration parameter range sets to different decision computing modules for other corresponding RF systems that are required to be calibrated.

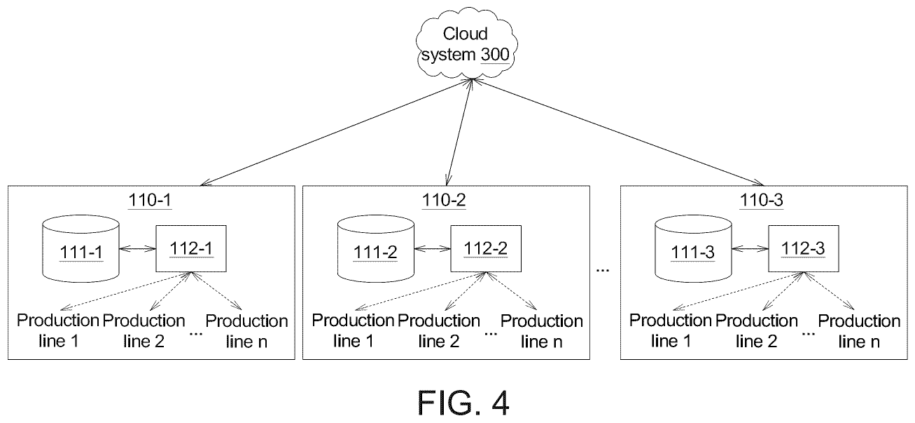

FIG. 4 is a diagram illustrating a cloud system 300 and multiple decision computing modules (such as 110-1 to 110-3), according to some implementations of the present disclosure. Specifically, the technique provided by the present disclosure may use Markov model as a decision base for selecting parameter adjusting ranges, and use edge computing architecture (such as edge computing processors 112-1 to 112-3) for generating Markov chain data required by the Markov decision, wherein the Markov chain data is stored by the corresponding calibration database (such as calibration databases 111-1 to 111-3). The calibration databases 111-1 to 111-3 are coupled to the cloud system 300 to store the Markov chain data (including multiple calibration parameter range sets) in the cloud system 300.

In this embodiment, as shown in FIG. 4, the cloud system 300 may connect to the calibration databases 111-1 to 111-3 located in different areas A to C (such as databases located in different areas or production bases), to compile all Markov chain data (including multiple calibration parameter range sets) of the same RF system or RF systems with similar characteristics from different production bases. Therefore, when the RF calibration device in one of the multiple areas A to C (such as the RF calibration device 100 in FIG. 1) lacks calibration data (such as Markov chain data), one of the decision computing modules 110-1 to 110-3 of the RF calibration device corresponding to one of the plurality of areas A to C can obtain the calibration data from other RF calibration devices in other one of areas A to C through the cloud system 300, thereby calibrating the RF system.

Therefore, each decision computing module can support the operation of multiple production lines in the local production base at the same time. In addition to collecting the calibration data used locally (such as Markov chain data), the cloud system 300 can also use the calibration data in other areas as a reference to calibrate the corresponding RF systems in different areas.

In some implementations, each calibration database 111-1 to 111-3 can store the processed calibration data (such as Markov chain data) used in the calibration process of each RF system, that is, including all process steps of the calibration from the beginning to the completion, and the value of the calibration parameter used by the RF system that has been calibrated can be updated in real time to each calibration database 111-1 to 111-3, and can be provided to the cloud database 310 of the cloud system 300.

FIG. 5 is a diagram illustrating an example Markov chain 500, according to some implementations of the present disclosure. In some implementations, each state (state S1 and state S2) of Markov chain used for calibrating RF system includes 4 factors, which are the in-phase signal DC offset calibration parameter Δδ_{I}′, the quadrature-phase DC offset calibration parameter Δδ_{Q}′, the gain calibration parameter Δg′ and the phase calibration parameter ΔØ′. The maximum adjustable range of each factor is determined by digits, as shown by FIG. 5. Wherein, the digit of Δg′ is ng, the digit of ΔØ′ is no, the digit of Δδ_{I}′ is n_{δI}, and the digit of Δδ_{Q}′ is n_{δQ}. Thus, the adjustable ranges of those 4 factors respectively are 0 to 2^{ng}−1, 0 to 2^{nφ}−1, 0 to 2^{nδI}−1, 0 to 2^{nδQ}−1. For simplifying description, we assume that each factor is 8 digits, thus the adjustable range of each factor is 0 to 255. However, actual correction value corresponding to the digit jitter change of each factor will be different according to the actual design of the product. For example, if the adjustable range of phase is within ±Π/4, the adjusting variation of each level of ΔØ′ is about 0.18°.

In the example of FIG. 5, each factor value in each state (state 1 and state 2) of the Markov chain is defined as a continuous interval range. For example, initial state S₁ (initial state) can be represented as [Δg′=(100, 150), ΔØ′=(10,15), Δδ_{I}′=(180,230), Δδ_{Q}′=(150, 190)]. It means that initial values of 4 factors of Markov decision are set within the foresaid range, and the calibration control module (such as the calibration control module 120 in FIG. 3) only uses the aforementioned range for beginning to calibrate RF system (or DUT) until the calibration is done in this state or the state needs to be changed (such as from state S1 to state S2).

As discussed above, the Markov chain used in the technique provided by the present disclosure is established by each decision computing module based on the data accumulated in local production, and, through collecting and analyzing data of each decision computing module by the cloud system, the calibration parameter ranges in each state are optimized to decrease the time took by the calibrating process in each state as much as possible. For example, if there are 10000 calibrating data, after analyzing, 6300 of Δg′=(110, 130), ΔØ′=(10,15), Δδ_{I}′=(200,230) and Δδ_{Q}′=(150, 170) are found, another 3500 of Δg′=(120, 135), ΔØ′=(13,20), Δδ_{I}′=(220,240) and Δδ_{Q}′=(160,170) are found, and last 200 data are Δg′=(90,95), ΔØ′=(25,35), Δδ_{I}′=(185, 195), and Δδ_{Q}′=(135, 145). In some implementations, as shown in FIG. 5, the initial state S₁ of Markov chain is set as [Δg′=(100, 135), ΔØ′=(10,20), Δδ_{I}′=(180,240), Δδ_{Q}′=(150,170)] to cover 97% (0.97) chance of success. The left 3% is changed to be tested in the state S₂ as set as [Δg′=(95,95), ΔØ′=(25,35), Δδ_{I}′=(150,175), Δδ_{Q}′=(135,145)] to cover 90% (0.9) chance of success.

FIG. 6 is a diagram illustrating another example Markov chain 600, according to some implementations of the present disclosure. The Markov chain data in the Markov chain 600 as shown in FIG. 6 includes more states (states S1 to S4), and thus calibration parameter range included by each status is smaller. Thus, comparing to the Markov chain data in the Markov chain 500 in FIG. 5, the decision computing module of the RF calibration device applying the Markov chain in FIG. 6 for calibrating RF system may decrease the time taken for the calibration. The Markov chain data in the Markov chain 600 shown in FIG. 6 are expressed in a manner similar to the Markov chain data in the Markov chain 500 in FIG. 5, and the explanation thereof are omitted here.

In some implementations, based on the Markov chain in FIGS. 5 and 6, the calibration control module of the RF calibration device may at least include a processor and a network interface. Through the network interface, the calibration control module can be simultaneously coupled to the RF system to be tested (or the DUT) and the decision computing module and the calibration analysis module of the RF calibration device. The calibration control module may calibrate the RF system according to provided calibration parameter range sets in the Markov chain state (such as through controlling and adjusting the RF system by the system processor of the RF system). Meanwhile, through the information fed back by the calibration analysis module, it determines whether the original provided calibration parameter range sets can continue to be used for calibration or the state must be changed for using calibration parameter range sets in another state of the Markov chain.

In some implementations, the calibration analysis module of the RF calibration device may include a physical machine or a virtual machine with an RF signal analysis function. The physical machine can be a stand-alone machine such as a signal analyzer (SA) or a composite machine of a signal generator (SG). A virtual machine refers to a device with signal analysis functions programmed as software. The software referred to herein, can be MATLAB, Python, Labview or other programmable application software.

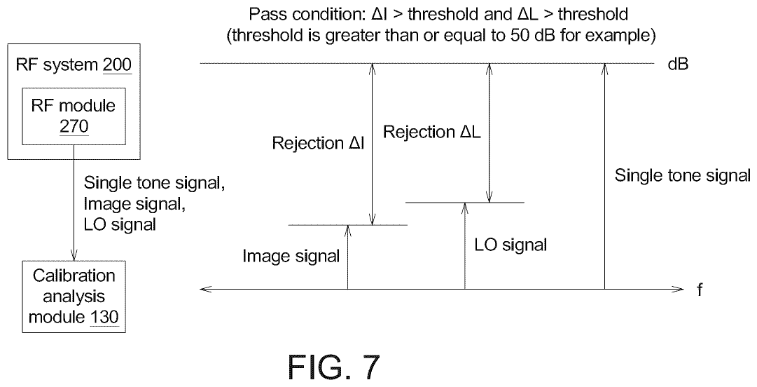

FIG. 7 is a diagram illustrating rejection relations between the corresponding LO signal and image signal, and the single tone signal of the RF output signal, according to some implementations of the present disclosure. By technique of RF calibration provided by the present disclosure, whether the calibration succeeds at the certain frequency point is determined based on the rejection ΔL between the single tone signal (such as output signal of RF module corresponding to certain frequency point of the RF system) and the LO signal coupled to the single tone signal (occurring at the output end), and based on the rejection ΔI between the single tone signal and generated image signal (noise signal). Therefore, during the calibration process, both of the rejection ΔL and rejection ΔI are required to be greater than a threshold to determine that the calibration of RF module (or entire RF system) corresponding to certain frequency point succeeds.

In some implementations, the threshold is set as 50 db. In some implementations, the threshold can be altered according to the actual situation, such as by the requirement of output signal quality. If the calibration analysis module detects that both the rejection ΔL and rejection ΔI are greater than the threshold, which means that the calibrating process of the RF module 270 corresponding to the certain frequency is completed, thus the calibration control module 120 will record the calibrating process of the RF module 270 (such as store used calibration parameter range sets to the calibration database) and then continue to calibrate other RF module corresponding to other frequency point, until calibrations of all respective RF module corresponding all frequency points in the RF system are done.

As discussed above, due to the IQ imbalance that may exist during the circuit generation process, the image signal (noise signal) may occur at the position of the image frequency, and, due to the DC offset of I and Q signals, the LO signal may occur at the output end. Thus, the higher rejection ΔL and the higher rejection ΔI represent that the output single tone signal is greater than the image signal and the LO signal, wherein the quality of the output signal from the RF system is increased. Therefore, the technique of RF calibration provided by the present disclosure uses the rejection ΔL and the rejection ΔI between the aforementioned single tone signal, and the LO signal and image signal at the output end as the basis for determining whether the calibration is successful.

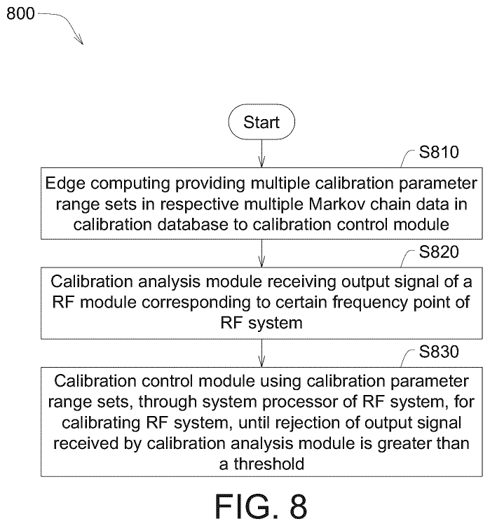

FIG. 8 is a flowchart illustrating an example RF calibration procedure 800 for calibrating RF module, according to some implementations of the present disclosure.

In step S810, an edge computing processor of decision computing module of an RF calibration device (such as the edge computing processor 112 of the decision computing module 110 of an RF calibration device 100) provides multiple calibration parameter range sets (such as states S1 to S2 in FIG. 5 or states S1 to S4 in FIG. 6) in respective multiple Markov chain data in the calibration database of the decision computing module (such as the calibration database 111 of the decision computing module 110 in FIG. 3) to a calibration control module of the RF calibration device (such as the calibration control module 120 of the RF calibration device 100 in FIG. 3).

In step S820, a calibration analysis module of the RF calibration device (such as the calibration analysis module 130 of the RF calibration device 100 in FIG. 3) receives an output signal (such as single tone signal ST) of an RF module (such as RF module 270 of FIG. 2) corresponding to a certain frequency point of an RF system (such as the RF system 200 of FIG. 2).

In step S830, the calibration control module uses calibration parameter range sets, through a system processor (such as the system processor 210 in FIG. 1) of the RF system, for calibrating the RF system, until a rejection (such as the rejection ΔL and rejection ΔI) of the output signal received by the calibration analysis module is greater than a threshold (such as 50 dB).

In certain configurations, the RF calibration procedure further includes: an edge computing processor of the decision computing module retrieving multiple calibration parameters from a calibration database of the decision computing module; and the edge computing processor generating the multiple Markov chain data according to the multiple calibration parameters. The multiple calibration parameters includes an In-phase DC offset calibration parameter, a Quadrature-phase DC offset calibration parameter, a gain calibration parameter and a phase calibration parameter, and the multiple Markov chain data include the plurality of calibration parameter range sets formed by the plurality of calibration parameters. The multiple calibration parameter range sets include range values of the multiple calibration parameters.

In certain configurations, the rejection includes an image signal rejection and a LO signal rejection. The image signal rejection is a difference value between the output signal of the RF system and an image signal generated by the RF system at other frequency, and the LO signal rejection is a difference value between the output signal of the RF system and a LO signal coupled to the output signal. The image signal rejection is associated with the gain calibration parameter and the phase calibration parameter, and the LO signal rejection is associated with the In-phase DC offset calibration parameter and the Quadrature-phase DC offset calibration parameter.

In certain configurations, the RF calibration procedure further includes, when the rejection of the output signal received by the calibration analysis module is greater than a threshold, the edge computing processor updating respective used values of the multiple calibration parameter range sets to the multiple calibration parameter range sets in the calibration database.

In certain configurations, the RF calibration procedure further includes: calibration databases of the RF calibration device and other RF calibration devices respectively providing the Markov chain data or other Markov chain data to a cloud system; the cloud system providing the multiple calibration parameter range sets in the Markov chain data or the other Markov chain data to the RF calibration device or the other RF calibration devices; and the cloud system receiving the Markov chain data or the other Markov chain data updated by the RF calibration device or the other RF calibration devices.

According to the implementations above, the RF calibration technique provided by the present disclosure uses an open-loop method to calibrate the DC offset of I and Q signals, and the IQ mismatch of the RF system (or DUT), and uses a Markov decision method to determine the adjustment ranges for each parameter. It can be applied to RF systems designed with discrete architectures or other architectures. Through the RF calibration technique provided by the present disclosure, the time for calibrating I and Q signals of the RF system with an open-loop method can be shortened and optimized, and the Markov model is used as the basis for optimal calibration decisions. A Markov chain database is established in the cloud and edge computing environment to calibrate the DC offset of I and Q signals and IQ mismatch of the RF system. Additionally, the RF calibration technique provided by the present disclosure does not directly measure the calibrated DC offset and the amplitude and phase values of I and Q signals, but analyzes the two rejections between the single tone signal, the LO signal, and the image signal, which can greatly shorten the time required for calibration, thereby reducing costs, and is suitable for automated production and testing environments.

The processes and logic flows described in this document can be performed by one or more programmable processors executing one or more computer programs to perform the functions described herein. The processes and logic flows can also be performed by, and apparatus can also be implemented as, special purpose logic circuitry, e.g., an FPGA (field programmable gate array) or an ASIC (application specific integrated circuit).

A computer program (also known as a program, software, software application, script, or code) can be written in any form of programming language, including compiled or interpreted languages, and it can be deployed in any form, including as a standalone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed for execution on one computer or on multiple computers that are located at one site or distributed across multiple sites and interconnected by a communications network.

The processes and logic flows described in this document can be performed by one or more programmable processors executing one or more computer programs to perform the functions described herein. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer can include a processor for performing instructions and one or more memory devices for storing instructions and data. Generally, a computer can also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data can include all forms of nonvolatile memory, media and memory devices, including by way of example semiconductor memory devices, e.g., EPROM, EEPROM, and flash memory devices; magnetic disks. The processor and the memory can be supplemented by, or incorporated in, special purpose logic circuitry.

While this document may describe many specifics, these should not be construed as limitations on the scope of an invention that is claimed or of what may be claimed, but rather as descriptions of features specific to particular embodiments. Certain features that are described in this document in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination in some cases can be excised from the combination, and the claimed combination may be directed to a sub-combination or a variation of a sub-combination. Similarly, while operations are depicted in the drawings in a particular order, this should not be understood as requiring that such operations be performed in the particular order shown or in sequential order, or that all illustrated operations be performed, to achieve desirable results.

Only a few examples and implementations are disclosed. Variations, modifications, and enhancements to the described examples and implementations and other implementations can be made based on what is disclosed.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. An RF calibration device, for calibrating an RF system, comprising:
a calibration control module, coupled to a system processor in the RF system;
a calibration analysis module, coupled to the calibration control module and the RF system and configured to receive an output signal from the RF system; and
a decision computing module, coupled to the calibration control module and configured to provide a plurality of calibration parameter range sets in a plurality of Markov chain data to the calibration control module,
wherein, the calibration control module provides the plurality of calibration parameter range sets to the system processor to enable the system processor to use the plurality of calibration parameter range sets for calibrating the RF system, until a rejection of the output signal received by the calibration analysis module is greater than a threshold.

2. The RF calibration device of claim 1, wherein the decision computing module comprising:
a calibration database, configured to store a plurality of calibration parameters; and
an edge computing processor, coupled to the calibration database, and configured to retrieve the plurality of calibration parameters and to generate the plurality of Markov chain data according to the plurality of calibration parameters,
wherein the plurality of calibration parameters includes an In-phase DC offset calibration parameter, an Quadrature-phase DC offset calibration parameter, a gain calibration parameter and a phase calibration parameter, and the plurality of Markov chain data include the plurality of calibration parameter range sets formed by the plurality of calibration parameters, wherein the plurality of calibration parameter range sets include range values of the plurality of calibration parameters.

3. The RF calibration device of claim 2, wherein the rejection includes an image signal rejection and a local oscillator (LO) signal rejection,
wherein the image signal rejection is a difference value between the output signal of the RF system and an image signal generated by the RF system at other frequency, and the LO signal rejection is a difference value between the output signal of the RF system and a LO signal coupled to the output signal,
wherein the image signal rejection is associated with the gain calibration parameter and the phase calibration parameter, and the LO signal rejection is associated with the In-phase DC offset calibration parameter and the Quadrature-phase DC offset calibration parameter.

4. The RF calibration device of claim 2, wherein when the rejection of the output signal received by the calibration analysis module is greater than a threshold, the edge computing processor updates respective used values of the plurality of calibration parameter range sets to the plurality of calibration parameter range sets in the calibration database.

5. The RF calibration device of claim 4, wherein the decision computing module is coupled to a cloud system, and the cloud system is coupled to other RF calibration devices,
wherein calibration databases of the RF calibration device and the other RF calibration devices respectively provide the Markov chain data or other Markov chain data to the cloud system, to enable the cloud system providing the plurality of calibration parameter range sets in the Markov chain data or the other Markov chain data to the RF calibration device or the other RF calibration devices, and the cloud system receives the Markov chain data or the other Markov chain data updated by the RF calibration device or the other RF calibration devices.

6. An RF calibration method, for calibrating an RF system, comprising:
providing, by a decision computing module of an RF calibration device, a plurality of calibration parameter range sets in a plurality of Markov chain data to a calibration control module of the RF calibration device;
receiving, by a calibration analysis module of the RF calibration device, an output signal of the RF system; and
providing, by the calibration control module, the plurality of calibration parameter range sets to a system processor of the RF system, to enable the system processor to use the plurality of calibration parameter range sets for calibrating the RF system, until a rejection of the output signal received by the calibration analysis module is greater than a threshold.

7. The RF calibration method of claim 6, further comprising retrieving, by an edge computing processor of the decision computing module, a plurality of calibration parameters from a calibration database of the decision computing module; and
Generating, by the edge computing processor, the plurality of Markov chain data according to the plurality of calibration parameters,
wherein the plurality of calibration parameters includes an In-phase DC offset calibration parameter, an Quadrature-phase DC offset calibration parameter, a gain calibration parameter and a phase calibration parameter, and the plurality of Markov chain data include the plurality of calibration parameter range sets formed by the plurality of calibration parameters, wherein the plurality of calibration parameter range sets include range values of the plurality of calibration parameters.

8. The RF calibration method of claim 7, wherein the rejection includes an image signal rejection and a LO signal rejection,
wherein the image signal rejection is a difference value between the output signal of the RF system and an image signal generated by the RF system at other frequency, and the LO signal rejection is a difference value between the output signal of the RF system and a LO signal coupled to the output signal,
wherein the image signal rejection is associated with the gain calibration parameter and the phase calibration parameter, and the LO signal rejection is associated with the In-phase DC offset calibration parameter and the Quadrature-phase DC offset calibration parameter.

9. The RF calibration method of claim 8, further comprising, when the rejection of the output signal received by the calibration analysis module is greater than a threshold, updating, by the edge computing processor, respective used values of the plurality of calibration parameter range sets to the plurality of calibration parameter range sets in the calibration database.

10. The RF calibration method of claim 9, further comprising:
providing, by calibration databases of the RF calibration device and other RF calibration devices respectively, the Markov chain data or other Markov chain data to a cloud system;
providing, by the cloud system, the plurality of calibration parameter range sets in the Markov chain data or the other Markov chain data to the RF calibration device or the other RF calibration devices; and
receiving, by the cloud system, the Markov chain data or the other Markov chain data updated by the RF calibration device or the other RF calibration devices.

11. A non-transitory computer readable storage medium, comprising a plurality of instructions, wherein the plurality of instructions enables a controller, a computing device or a computer to perform the RF calibration method of claim 6.
